(19) United States
(12) Patent Application Publication
(10) Pub. No.: US 2014/0361141 A1
(43) Pub. Date: Dec. 11, 2014

(54) TRACKING SYSTEM

(71) Applicants: Darrell Edward COLEMAN, New Castle, DE (US); Wallace Levi COLEMAN, New Castle, DE (US)

(72) Inventors: Darrell Edward COLEMAN, New Castle, DE (US); Wallace Levi COLEMAN, New Castle, DE (US)

(21) Appl. No.: 14/301,513

(22) Filed: Jun. 11, 2014

Related U.S. Application Data
(60) Provisional application No. 61/833,499, filed on Jun. 11, 2013.

(51) Int. Cl. F16M 11/20; H05K 5/02

(52) U.S. Cl. CPC F16M 11/2014; H05K 5/0217
USPC 248/550

(57) ABSTRACT

Tracking systems that allow a portable electronic device to record a target as it moves includes a holder for a portable electronic device, a tracking element coupled to the holder that follows or tracks a target as the target moves; and a positioning element coupled to the holder that pans and rotates as the tracking element tracks the object. Alternative configurations include a combination holder/positioning element, which is incorporated into the system.

### CROSS-REFERENCE TO RELATED APPLICATION

This application claims priority to U.S. Application Ser. No. 61/833,499, filed Jun. 11, 2013, the entirety of which is incorporated herein by reference.

### BACKGROUND OF THE DISCLOSURE

Portable electronic devices such as phones, tablets, game consoles, etc., frequently incorporate video and audio recording devices. For a portable electronic device to record, however, a user has perform multiple steps. Some of these steps include initiating an application on the portable electronic device, holding the device by hand, positioning or pointing the device toward a target, and manually following and tracking the target. While a user may purchase a docking station for their portable electronic device, docking stations are typically not provided with a base, holder, or other component that can adjust position of the portable electronic device and follow or track a target.

Given these considerations, among others, there is a clear need for tracking systems configured to dock portable electronic devices and follow or track a target for recording purposes. The present invention fulfills this need and provides further related advantages, as described herein.

### BRIEF SUMMARY OF THE DISCLOSURE

The present invention relates to tracking systems that allow a portable electronic device to record a target as it moves. One configuration for a tracking system includes a holder for a portable electronic device, a tracking element coupled to the holder that follows or tracks a target as the target moves, and a positioning element coupled to the holder that pans, tilts, and/or rotates as the tracking element follows or tracks the object. In alternative configurations, a combination holder/positioning element may incorporated into the system rather than a separate holder and positioning element.

### BRIEF DESCRIPTION OF THE SEVERAL VIEWS OF THE DRAWINGS

The drawings herein are for illustrative purposes only and are not intended to limit the scope of the present disclosure. In the drawings:

FIG. 1 shows one configuration of a tracking system with a portable electronic device;

FIG. 2 shows an elevated top view the tracking system shown in FIG. 1 without a portable electronic device;

FIG. 3 shows a perspective view of the tracking system shown in FIG. 1, indicating that the system is tracking a target;

FIG. 4A shows a top perspective view of a combination holder/positioning element;

FIG. 4B shows a bottom perspective view of the combination holder/positioning element shown in FIG. 4A;

FIG. 5A shows a top perspective view of an alternative base configuration;

FIG. 5B shows a bottom perspective view of the alternative base configuration shown in FIG. 5A; and

FIG. 6 shows a top perspective view of an electronics panel.

### DETAILED DESCRIPTION OF THE DISCLOSURE

The foregoing summary, as well as the following detailed description of the disclosure, will be better understood when read in conjunction with the appended drawings. For the purpose of illustrating the disclosure, there are shown in the drawings embodiments or configuration which are preferred. It should be understood, however, that the invention is not limited to the precise arrangements and instrumentalities shown and described herein.

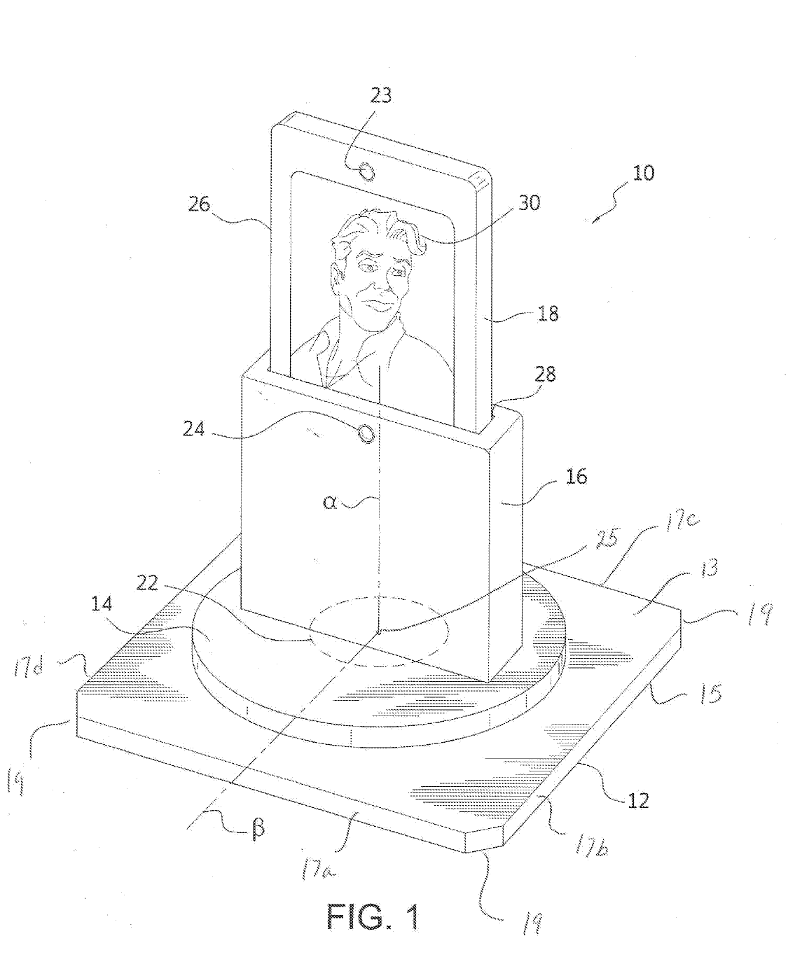

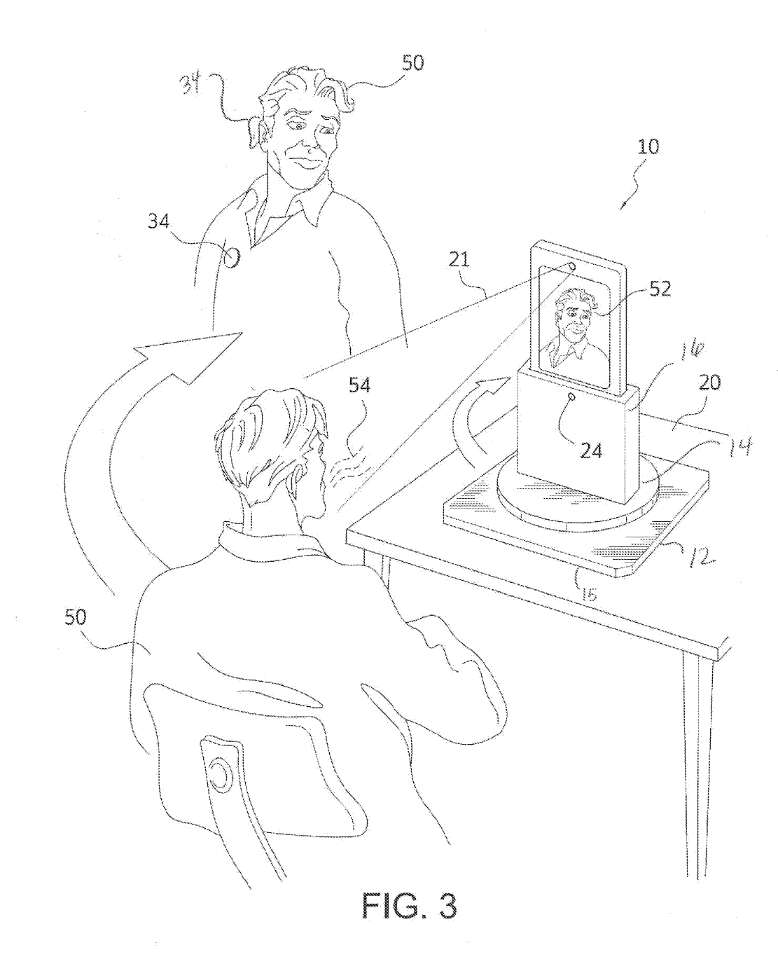

Turning in detail to the drawings, FIGS. 1-3 show one configuration of a tracking system 10, which includes a base 12, a positioning element 14, and a holder 16 for a portable electronic device 18. The base 12 is provided for support of the system 10 and is coupled to the positioning element 14. The base basically acts as a platform and includes an upper surface 13, a bottom surface 15, and sidewalls 17a, 17b, 17c, and 17d. Corners 19 of the base may be optionally chamfered or rounded. When the tracking system 10 is in use, the bottom surface 15 of the base 12 is preferably positioned on a substantially flat surface 20 such as a countertop, desk, table, or other surface that provides stability, as particularly shown in FIG. 3. Although the base 12 is shown as a substantially flat plate-like material, the base may be any shape that provides enough stability for the system 10 to track a target 50, as the target moves to and from various positions within a field of view 21 (FIG. 3) of a recording device 23 incorporated in or disposed on the portable electronic device 18. For example, the base 12 may be configured as a tripod, podium, or other upright device, providing a relatively stable surface for recording purposes.

As used herein, a portable electronic device is defined as any type of portable device capable of recording images and/or sounds, e.g. tablets, cellular phones, cameras, pagers, computers, text messaging devices, music devices, game consoles, recorders, etc. Portable electronic devices include devices manufactured and/or sold by Apple Inc., Samsung, Research In Motion (Blackberry), Amazon, Barnes & Noble, Sony, and other similar manufacturers of portable electronic devices configured for recording.

Also as used herein, unless indicated otherwise, the term “record” and variations thereof refers to visual recordation of one or more objects and/or persons. Visual recordation, however, is not limited to recording objects in motion and may include still images taken using cameras and other types of photographic/recording devices.

As shown in FIG. 1, positioned between the positioning element 14 and the base 12 is a positioning/swivel mechanism 22 that allows the positioning element 14 to pan (i.e. move left, right, up and down) and swivel (i.e. turn clockwise and counter clockwise 360 degrees or less with respect to a central axis α). The positioning/swivel mechanism 22 may also allow the positioning element 14 to turn or tilt a predetermined angular range with respect to axes a and 13, for example. The positioning/swivel mechanism 22 may be any device suitable for positioning between the base and the positioning element such that tracking of a target 50 (FIG. 3) by the system is achievable. For example, the positioning element 14 may include components such as shafts, pins, gears, cams, or ball joints (not shown) which are configured to pan, tilt, and/or rotate in various directions upon application of forces resulting from the system. Such forces may be generated through electronic, heat-sensitive, and/or magnetic elements associated with one or more tracking elements 24 and following elements 34 (FIG. 3), as further described below. Preferably, the positioning element 14 is located at or near an intersection point 25, where axis a and 13 intersect.

Coupled to the positioning element 14 is a holder 16 for docking of a portable electronic device 18. The holder 16 may be configured differently, depending on the shape and size of the portable electronic device 18. In alternative configurations, the holder and the base are affixed to each other or manufactured as a one-piece component, which is capable of movement when the system is initiated or triggered.

The base and holder may each be configured to have a size, outer shape and perimeter that will accommodate various types of portable electronic devices. For example, the base and holder may be configured to accommodate devices that are suitable to hold handheld phones and computer tablets. These devices include, but are not limited to, phone and tablet devices sold by Apple, Samsung, Research in Motion (Blackberry). For this type of application of the system, a user of the tracking system can hold the system by hand or alternatively place the device in a stand or other area that provides sufficient stability for recording. Alternatively, the base and the holder may be configured to accommodate “larger” electronic devices such as monitors and flat screen televisions (e.g. those capable of connecting wirelessly to an internet service provider). The base and holder may also be configured to be mobile or coupled to a mobile unit that allows the system to track the target during movement and follow the target as it moves from one location to another. Preferably, the mobile unit is such that it can maneuver around objects in a home or office, particularly objects located in small spaces.

If the portable electronic device 18 is a tablet device 26 or a cellular phone, the holder 16 can be configured to a size and shape such that it is capable of partially housing the portable electronic device 18. FIGS. 1 and 3, for example, shows a portable electronic device 18 configured as a tablet device 26. The tablet device 26 has a predefined length, width and thickness, and viewing space 30 for recording. A recording device 23, such as a camera or other type of device capable of still, video, and/or audio recording is incorporated in or disposed on the portable electronic device 18.

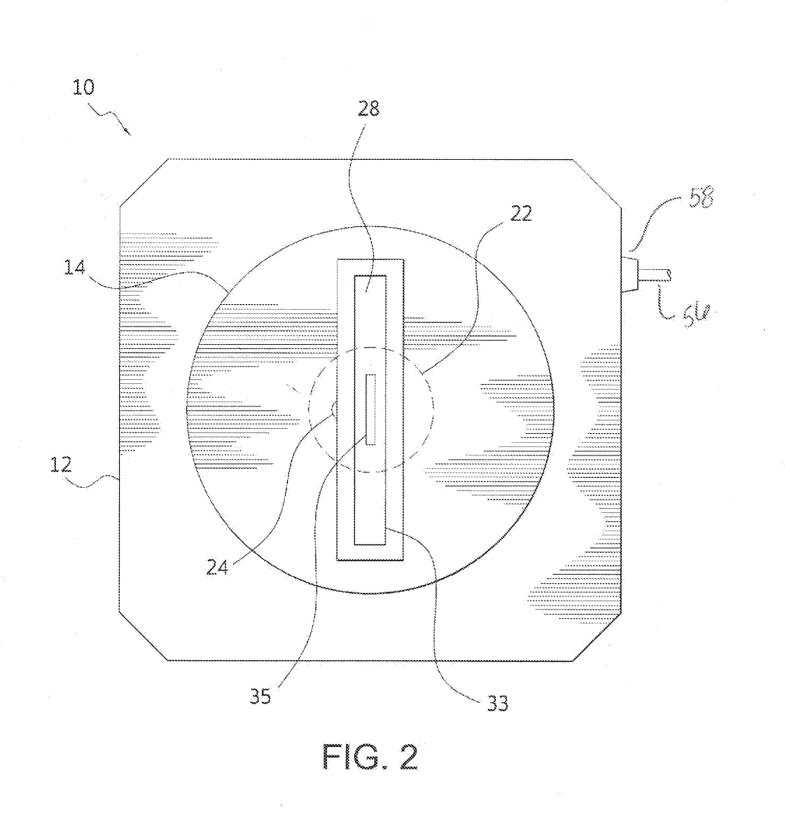

Based upon the dimensions of the portable electronic device 18, the holder 16 is provided with a recess 28 configured to securely position the portable electronic device for recording. As particularly shown in FIG. 1, the tablet device 26 may be positioned on the holder and in the system such that its viewing screen is not obstructed. Referring to FIG. 2, alternatively, the holder 16 may be provided with a cradle 33 that positions the device 18 on the holder. Alternatively or in addition to the cradle, a charging element 35 may fit fully or partially within the portable electronic device such that the device is supplied with power, particularly for recording purposes.

Incorporated in or disposed on the holder 16 and/or the positioning element 14 is a tracking element 24. Preferably, the tracking element 24 is electronically or magnetically coupled to a complimentary following element 34 disposed on the target 50, as shown in FIG. 3. The tracking element 24 may be any type of sensor or magnetic element coupled to the tracking element 24 such that movement of the positioning element is initiated when the system is in use. Where the tracking element 24 is a sensor, the following element 34 may be configured as a transmitter capable of producing a signal. The transmitter could be disposed on the target 50, for example. The transmitter may be clipped onto the target, for example, using a pin or other type of fastening device. Alternatively, transmitter may be incorporated into a secondary electronic device such an electronic pointer, phone, or Bluetooth-enabled component, etc., which is positioned on the target such that following or tracking of the target may be achieved.

According to one configuration, one or more infrared sensors may be coupled to the system and configured to pick up heat emanating from a target 50. The sensor may be, for example, programmed to pick up a specific heat signature that is emanating from the target. A circuit/development board 51, including a microcontroller 53, may also be incorporated into the system to pick up information transmitted by the sensor, as shown by way of example in FIG. 7. Preferred microcontrollers include, but are not limited to, single-board microcontrollers, which are well-known in the art for use in the application of interactive environments. The board 51 may also be electrically coupled to a servomechanism, which is coupled to the positioning/swivel mechanism 22.

In a configuration where the tracking element is a transmitter, when activated, the transmitter is picked up by the sensor, causing the sensor to lock onto the transmitter. In turn, the sensor communicates with the positioning/swivel mechanism 22 such that panning, tilting, and/or rotation of the positioning element may be initiated. When the transmitter is deactivated, the system will no longer track the target. Where the tracking element 24 is a magnetic element, the following element 34 is also configured as a magnetic element. Both devices are configured to generate magnetic fields that cause the tracking element to lock on to the target, causing the system to follow the target during movement.

When in use, the tracking system 10 will track a target during movement, thereby allowing the portable electronic device 18 to capture images 52 of a target and/or sounds 54 emanating from the target. The system 10 is particularly suited for video conferencing applications, e.g. Face Time, Skype and ooVoo, included in or added to many portable electronic devices. Preferably, the system 10 is placed in a central location that allows the system to track the target as it moves to and from various positions.

The tracking element 24 may also be activated to initiate a software application (app) located within the portable electronic device such that the tracking element 24 and/or the following element 34 may capture positioning data of the target 50 and possibly anticipate motion of the target for recording purposes.

In preferred configurations the tracking system 10 is battery powered and capable of connection to a separate power source via a cord 56 that is integral to or separate from the system. The cord 56 may be coupled to the base 12, as particularly shown in FIG. 2, via a connection element 58.

The tracking system 10 may also include a remote element (not shown) or be configured for connection to a remote. The remote element is preferably configured to initiate functions of the tracking system and/or the portable electronic device. Preferably, the remote element is capable of controlling the tracking system, recording devices, and/or other applications (apps) of the portable electronic device.

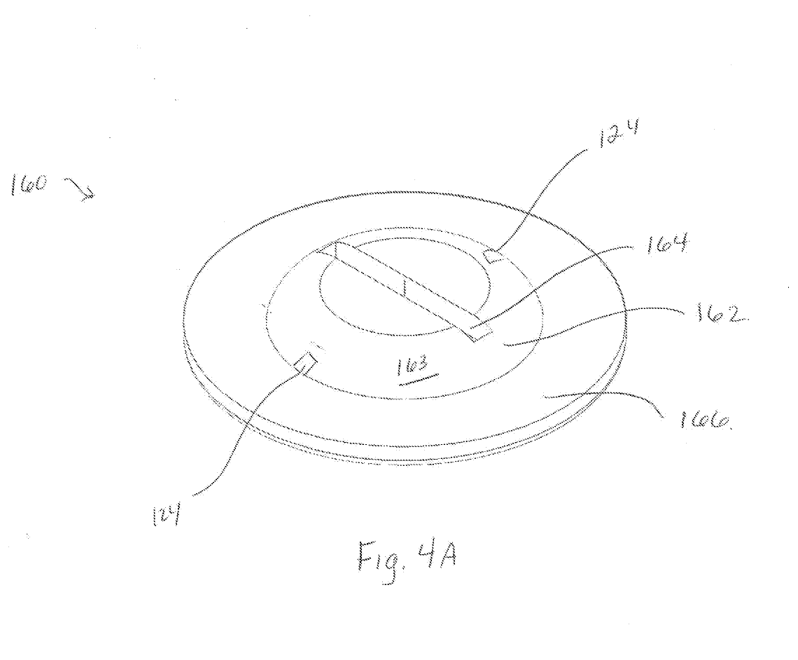

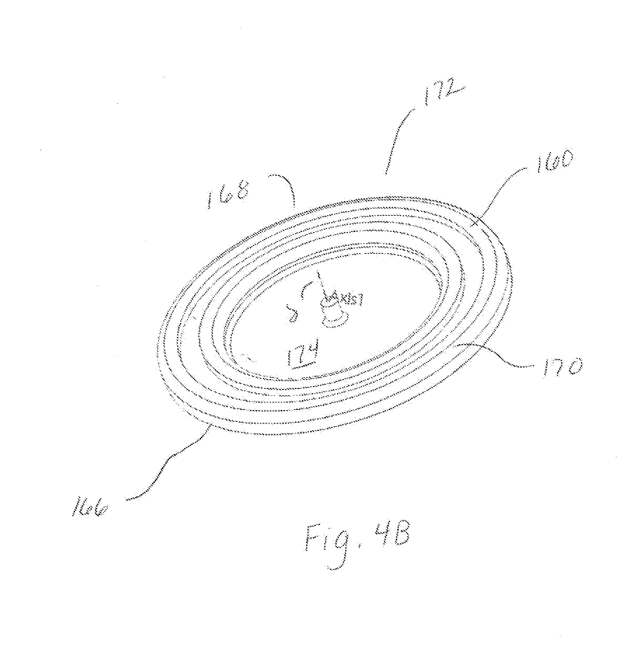

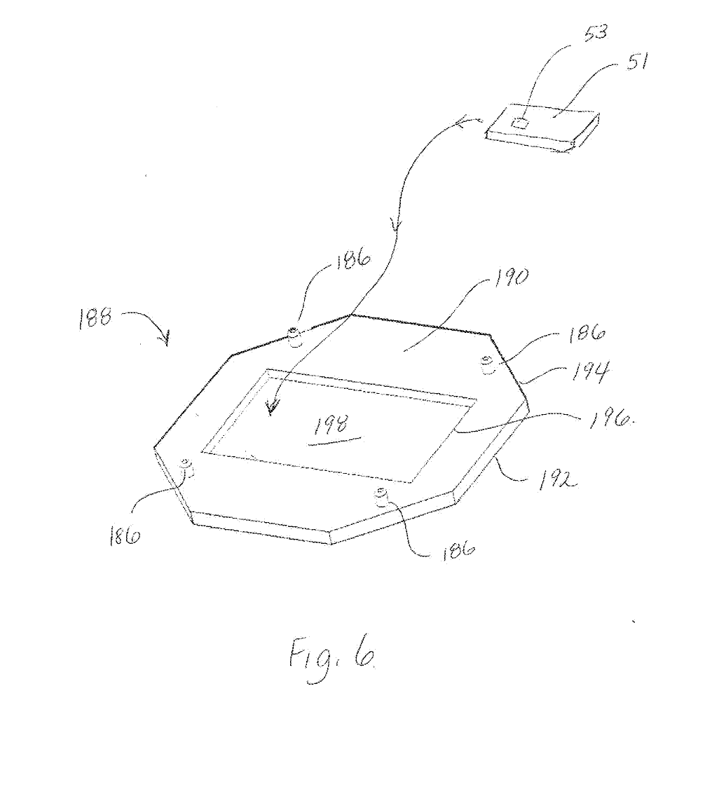

FIGS. 4A-6 show alternative elements that may be incorporated into the tracking system 10. FIGS. 4A and 4B respectively show top and bottom perspective views of a combination holder/positioning element 160, which may be incorporated into an alternative tracking system configuration. Rather than a holder, which extends upwardly, as shown in FIGS. 1 and 3, the combination holder/positioning element 160 includes a protruding element 162 with a device recess 164 incorporated therein. The protruding element 162 is integrally connected to a platform 166. The holder/positioning element 160 also includes tracking elements 124 disposed on the outer surface 163 of the protruding element 162. The underside 168 of the combination holder/positioning element 160 includes a contoured surface 170, having a plurality of ridges 172 and a substantially flat underside area 174, and a pin element 176 disposed centrally with respect to the underside area. The pin element 174 is capable of rotating with respect to a central axis 6.

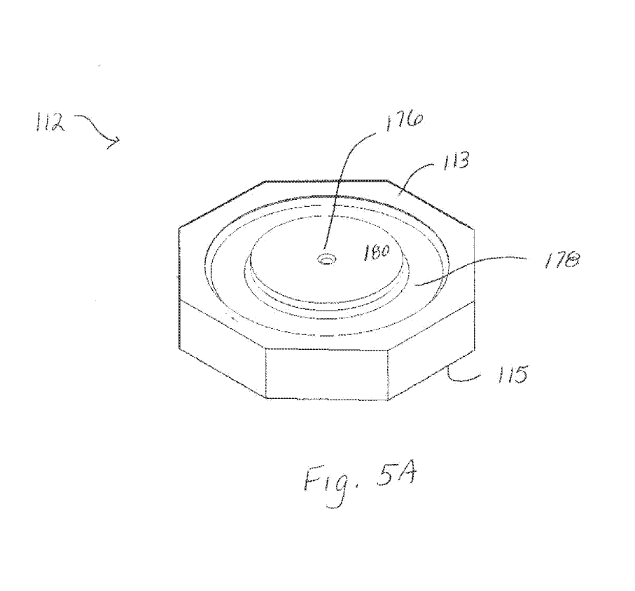

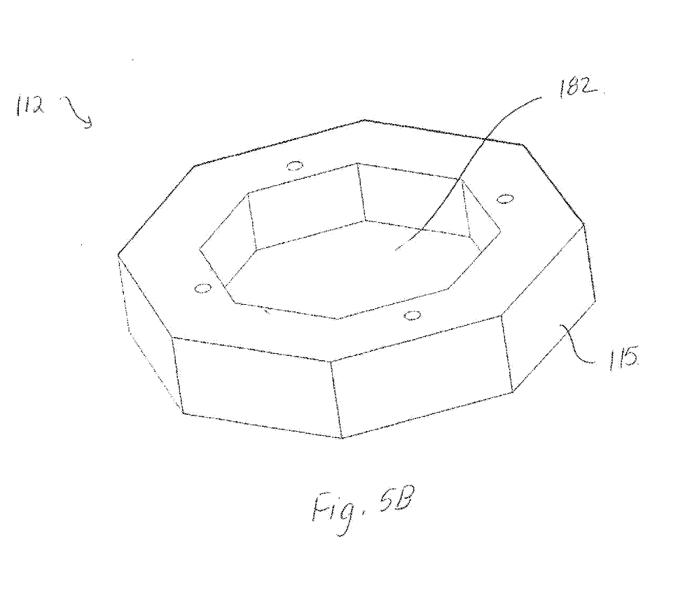

The pin element 174 fits within a pin hole 176 located on top surface 113 of an alternative base 112, as shown in FIGS. 5A and 5B The base 112 also includes a bottom surface 115, a plurality of sidewalls 117, a platform recess 178 and an upper surface 180. The platform recess 178 and upper surface 180 are, respectively, complementary to the platform 166 and the underside area 174 of the combination holder/positioning element 160. The alternative base also preferably includes and a bottom recess 182 (FIG. 5B) and connection holes 184, as shown in FIG. 5B.

Mating pins 186 of an electronics panel 188 are configured to mate with connection holes 184 such that the electronic panel 188 has a snap fit with the alternative base 112. The electronic panel includes a top surface 190, a bottom surface 192, and sidewalls 194. The electronic panel 188 is of sufficient thickness such that a panel recess 196 forms an interior surface 198.

All components of the tracking system 10 are preferably manufactured from relatively lightweight materials having mechanical properties such that deformation will not significantly occur over long periods of use. System component materials may include, but are not limited to, thermoplastics, metallic based materials, elastomeric materials, ceramic materials, and/or a combination of these materials.

While embodiments of this invention have been shown and described, it will be apparent to those skilled in the art that many more modifications are possible without departing from the inventive concepts herein. The invention, therefore, is not to be restricted, except in the spirit of the following claims.

What is claimed is:

1. A tracking system, comprising:
a holder for a portable electronic device;
a tracking element coupled to the holder configured to follow or track a target during movement; and
a positioning element coupled to the holder configured to move as the tracking element tracks the object.

2. The tracking system of claim 1, further comprising a base coupled to the holder.

3. The tracking system of claim 1, wherein the tracking element is incorporated into the holder.

4. The tracking system of claim 1, wherein the tracking element is disposed on the holder.

5. The tracking system of claim 1, wherein the positioning element is configured to rotate.

6. The tracking system of claim 1, wherein the positioning element is configured to pan and rotate.

7. The tracking system of claim 1, wherein the positioning element is configured pan, rotate, and tilt.

8. The tracking system of claim 1, further comprising positioning/swivel mechanism coupled to the positioning element.

9. The tracking system of claim 8, wherein the positioning/swivel mechanism is configured as a shaft.

10. A tracking system, comprising:
a base;
a holder disposed on the base and configured to partially house a portable electronic device;
a tracking element coupled to the base configured to track a target during movement; and
a positioning element coupled to the holder configured to move as the tracking element tracks the target.

11. The tracking system of claim 10, wherein the tracking element is disposed on an outer surface of the holder.

12. The tracking system of claim 1, wherein the tracking element comprises a sensor.

13. The tracking system of claim 12, wherein the sensor is configured for coupling with a following element.

14. The tracking system of claim 12, wherein the sensor is configured to sense heat.

15. The tracking system of claim 12, wherein the sensor is an infrared sensor.

16. A tracking system, comprising:
a tracking element configured to track a target during movement; and
a combination holder/positioning element, having a recess configured to hold a portable electronic device and at least one positioning element configured to move as the tracking element tracks the target.

17. The tracking system of claim 1, wherein the tracking element comprises a sensor.

18. The tracking system of claim 12, wherein the sensor is configured for coupling with a following element.
